(19) United States
(12) Patent Application Publication
(10) Pub. No.: US 2004/0245620 A1
(43) Pub. Date: Dec. 9, 2004

(54) Memory card capable of indicating an inserting direction

(76) Inventors: Jackson Hsieh, Hsinchu Hsien (TW); Jichen Wu, Hsinchu Hsien (TW); Worrell Tsai, Hsinchu Hsien (TW)

Correspondence Address: PRO-TECHTOR INTERNATIONAL, 20775 Norada Court, Saratoga, CA, 95070-3018, US

(21) Appl. No.: 10/454,656

(22) Filed: Jun. 3, 2003

(51) Int. Cl. H01L 23/52

(52) U.S. Cl. 257/690

(57) ABSTRACT

A memory card for being electrically connected to an electrical device. The memory card includes a substrate, and at least one memory chip. The substrate is formed with a plurality of contact leads, which is electrically connected to the electrical device when the substrate is inserted into the electrical device. The plurality of contact leads includes a long contact lead and a short contact lead to indicate an inserting direction of the substrate into the electrical device. The memory chip is mounted to the substrate and electrically connected to the plurality of contact leads.

### BACKGROUND OF THE INVENTION

1. Field of the Invention

The invention relates to a memory card, and more particularly to a memory card with an indicated inserting direction.

2. Description of the Related Art

Referring to FIG. 1, a conventional memory card includes at least one memory chip 16 and a substrate 10 on which a plurality of contact leads 12 is formed. When the substrate 10 is inserted into an electrical device (not shown), the contact leads 12 may be electrically connected to the electrical device. The substrate 10 is formed with a cut corner 14 to indicate a direction along which the substrate 10 may be inserted into the electrical device. The memory chip 16 is mounted to the substrate 10 and is electrically connected to the contact leads 12.

When the memory card is used, the cut corner 14 indicates the inserting direction of the substrate 10 into the electrical device. Thus, the contact leads 12 may be electrically connected to the electrical device.

However, when the memory card is manufactured, the substrate 10 has to be cut to form the cut corner 14. Thus, the manufacturing processes are inconvenient, and the manufacturing cost is high. Furthermore, if the position of the cut corner is incorrect, the product cannot be used and has to be thrown away.

### SUMMARY OF THE INVENTION

An object of the invention is to provide a memory card that may be manufactured easily in low cost.

To achieve the above-mentioned object, the invention provides a memory card for being electrically connected to an electrical device. The memory card includes a substrate, and at least one memory chip. The substrate is formed with a plurality of contact leads, which is electrically connected to the electrical device when the substrate is inserted into the electrical device. The plurality of contact leads includes a long contact lead and a short contact lead to indicate an inserting direction of the substrate into the electrical device. The memory chip is mounted to the substrate and electrically connected to the plurality of contact leads.

Forming the contact leads with different lengths may easily indicate the inserting direction of the substrate into the electrical device, so the manufacturing processes are convenient and the manufacturing cost is low.

### BRIEF DESCRIPTION OF THE DRAWINGS

FIG. 1 is a top view showing a conventional memory card.

FIG. 2 is a top view showing a memory card of the invention.

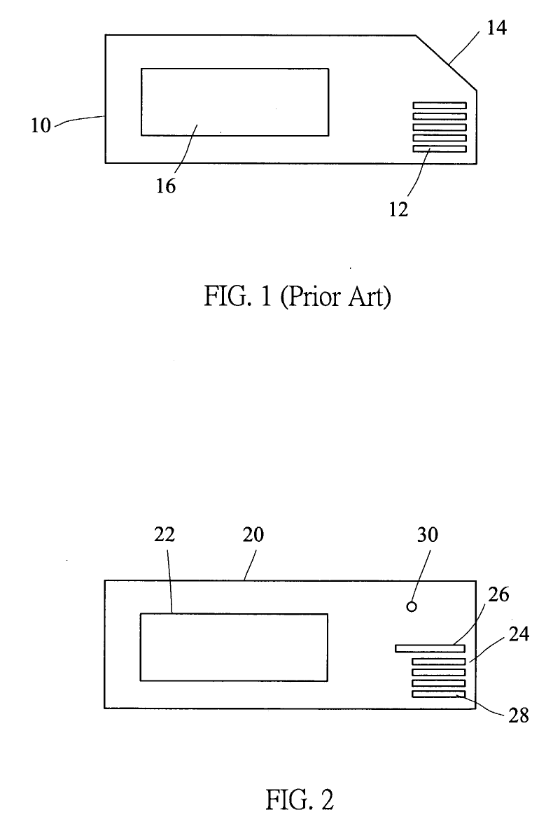

### DETAILED DESCRIPTION OF THE INVENTION

Referring to FIG. 2, a memory card of the invention includes a substrate 20 and at least one memory chip 22.

The substrate 20 is formed with a plurality of contact leads 24. When the substrate is inserted into an electrical device (not shown), the contact leads 24 may be electrically connected to the electrical device. The contact leads 24 include a long contact lead 26 and a short contact leads 28 to indicate the inserting direction of the substrate 20 into the electrical device. In this embodiment, a mark 30 is further formed at a lateral side of the long contact lead 26 to indicate the inserting direction of the substrate 20 more clearly.

The memory chip 22 is mounted to the substrate 20 and is electrically connected to the contact leads 24.

The inserting direction of the substrate 20 may be easily indicated by forming the contact leads 24 with different lengths or by forming a mark 30 on the substrate 20. Thus, the manufacturing processes are convenient, and the manufacturing cost may be reduced. In addition, the invention is free from wasting substrates caused by incorrect cutting in the prior art.

While the invention has been described by way of an example and in terms of a preferred embodiment, it is to be understood that the invention is not limited to the disclosed embodiment. To the contrary, it is intended to cover various modifications. Therefore, the scope of the appended claims should be accorded the broadest interpretation so as to encompass all such modifications.

What is claimed is:

1. A memory card for being electrically connected to an electrical device, the memory card comprising:
a substrate formed with a plurality of contact leads, which is electrically connected to the electrical device when the substrate is inserted into the electrical device, the plurality of contact leads including a long contact lead and a short contact lead to indicate an inserting direction of the substrate into the electrical device; and
at least one memory chip, which is mounted to the substrate and electrically connected to the plurality of contact leads.

2. The memory card according to claim 1, wherein a mark is formed on the substrate at a lateral side of the long contact lead to further indicate the inserting direction of the substrate into the electrical device.

3. A memory card for being electrically connected to an electrical device, the memory card comprising:
a substrate formed with a plurality of contact leads, which is electrically connected to the electrical device when the substrate is inserted into the electrical device, a mark being formed on the substrate at a lateral side of the contact leads to indicate an inserting direction of the substrate into the electrical device; and
at least one memory chip, which is mounted to the substrate and electrically connected to the contact leads.

4. The memory card according to claim 3, wherein the plurality of contact leads includes a long contact lead and a short contact lead, and the mark being formed at a lateral side of the long contact lead.
